(19) United States
(12) Patent Application Publication
(10) Pub. No.: US 2008/0237767 A1
(43) Pub. Date: Oct. 2, 2008

(54) Sensor-type semiconductor device and manufacturing method thereof

(75) Inventors: Chang-Yueh Chan, Taichung (TW); Chien-Ping Huang, Taichung (TW); Chih-Ming Huang, Hsinchu Hsein (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/080,002

(22) Filed: Mar. 31, 2008

(30) Foreign Application Priority Data
Apr. 2, 2007 (TW) 096111544

(51) Int. Cl. H01L 31/0203; H01L 31/18

(52) U.S. Cl. 257/433; 438/66; 257/E31.117; 257/E31.119; 257/E31.124; 257/E21.499

(57) ABSTRACT

A sensor-type semiconductor device and manufacturing method thereof are disclosed. The method includes providing a wafer comprising a plurality of sensor chips; forming concave grooves between the solder pads formed on the active surface of adjacent sensor chips; filling a filling material into the concave grooves and forming first conductive circuits electrically connecting the solder pads of adjacent sensor chips; mounting a light permeable body on the active surface of the wafer and thinning the non-active surface of the wafer to expose the filling material; mounting the wafer on a carrier board with second conductive circuits formed thereon corresponding in position to the filling material; forming first openings by cutting the light permeable body and the wafer to a position at which the second conductive circuits are located; forming metallic layers in the first openings by electroplating, the metallic layers electrically connecting the first and second conductive circuits of adjacent sensor chips; forming second openings by cutting the metallic layers to break the first conductive circuit connections and the second conductive circuit connections of adjacent sensor chips and meanwhile keep the first and second conductive circuits of each sensor chip still electrically connected through the metallic layers; filling a dielectric material into the second openings and removing the carrier board; and separating each of the sensor chips to form a plurality of sensor-type semiconductor devices. The invention overcomes the drawbacks of the prior art such as slanting notches formed on the non-active surface of the wafer, displacement of the notches due to the difficulty in precise alignment, as well as broken joints caused by concentrated stress generated in the slanting notches and exposed circuits.

### BACKGROUND OF THE INVENTION

1. Field of the Invention

The present invention relates generally to sensor-type semiconductor devices and manufacturing method thereof, and more particularly to WLCSP (Wafer-Level Chip Scale Package) sensor-type semiconductor devices and manufacturing method thereof.

2. Description of Related Art

Conventionally, an image sensor package is obtained by mounting a sensor chip to a chip carrier and electrically connecting the senor chip to the chip carrier through bonding wires and covering top surface of the sensor chip with a glass such that image light can be captured by the sensor chip. The image sensor packages can further be integrated with external devices such as printed circuit boards (PCBs) so as to be applied in various kinds of electronic products such as digital cameras, digital videos, optical mice, mobile phones and so on.

Meanwhile, with rapidly increasing of the volume of information transmission, as well as miniaturization of electronic products, integrated circuits are required to have large number of I/O ports, high heat dissipation efficiency and miniaturized size and packages of the integrated circuits are required to have high electrical performance and small size. Therefore, WLCSP (Wafer-Level Chip Scale Package) sensor-type semiconductor devices with a size only slightly bigger than sensor chips thereof have been developed and efficiently applied in small sized electronic products.

Referring to FIGS. 1A to 1H, U.S. Pat. No. 6,777,767 discloses a sensor-type semiconductor device and a manufacturing method thereof. First, as shown in FIG 1A, a wafer 10A having a plurality of sensor chips 10 is provided and conductive circuits 11 are formed between solder pads 101 of adjacent sensor chips 10 by sputtering. Then, as shown in FIG 1B, a glass 12 is adhered to the conductive circuits 11 through an adhesive layer 13. As shown in FIG. 1C, back side of the wafer 10A is thinned. As shown in FIG. 1D, the back side of the wafer 10A is notched corresponding to the conductive circuits 11 between the sensor chips 10 using a cutting tool and then plasma etched so as to expose the conductive circuits 11. Further, as shown in FIG. 1E, another glass 15 and a dielectric layer 16 are attached to the back side of the wafer 10A through an adhesive material 14. As shown in FIG. 1F, the dielectric layer 16, the glass 15, the adhesive material 14, and the conductive circuits 11 are notched again so as to form notches 17. Then, as shown in FIG 1G electrical contacts 18 are formed on surfaces of the notches 17 and the dielectric layer 16 close to the notches 17 by sputtering, wherein the electrical contacts 18 are electrically connected with the conductive circuits 11. Thereafter, bumps 19 are formed on bottom of the electrical contacts 18 and the whole package is singulated so as to yield a plurality of WLSCP sensor-type semiconductor devices, as shown in FIG 1H.

However, as the semiconductor devices have a reverse-trapezoid shape structure, a sharp angle is formed in joints of the electrical contacts and the corresponding conductive circuits, which causes the connection between the electrical contacts and the conductive circuits to break easily in case of a concentrated stress. Further, the notch formed at the back side of the wafer may be formed at a position deviate from a predefined position because of the difficulty in precise alignment. As a result, circuit connections cannot be established between the subsequently formed electrical contacts and the corresponding conductive circuits and even the chips can be damaged.

Meanwhile, the exposed electrical contacts can easily be polluted and accordingly the product reliability is decreased. Especially, when the bumps are reflowed for electrically connecting the semiconductor device to an external device such as a printed circuit board, the exposed electrical contacts may lead to a short circuit problem. Further the sputtering process used to form the conductive circuits and the electrical contacts complicates the manufacturing process. Also, the sputtering process and the plasma etching process result in an increased manufacturing cost.

Therefore, how to provide a sensor-type semiconductor device and a manufacturing method thereof that can overcome the above drawbacks has become urgent.

### SUMMARY OF THE INVENTION

According to the above drawbacks, an objective of the present invention is to provide a sensor-type semiconductor device and a manufacturing method thereof so as to avoid broken joints of circuits due to a sharp angle.

Another objective is to provide a sensor-type semiconductor device and a manufacturing method thereof, through which can prevent circuits from being exposed and protect the circuits from being polluted by external environment so as to ensure product reliability and keep reliable external electrical connection.

A further objective is to provide a sensor-type semiconductor device and a manufacturing method thereof, which can prevent the prior art alignment error during cutting the back side of the wafer and accordingly prevent such problems as poor electrical connection and chip damage.

Still another objective is to provide a sensor-type semiconductor device and a manufacturing method thereof, which avoids using the plasma etching process and too much sputtering process so as to simplify the manufacturing process and decrease the manufacturing cost.

To achieve the above and other objectives, the present invention discloses a manufacturing method of a sensor-type semiconductor device, which comprises the steps of: providing a wafer comprising a plurality of sensor chips, wherein the wafer and each sensor chip have an active surface and a non-active surface opposed to the active surface, a sensor area and a plurality of solder pads are disposed on the active surface of each sensor chip, and a plurality of concave grooves is formed between the solder pads of adjacent sensor chips; filling a filling material into the concave grooves and forming first conductive circuits on the filling material for electrically connecting the solder pads of adjacent sensor chips; disposing a light permeable body on the wafer for covering the sensor areas and thinning the non-active surface of the wafer to a position where the concave grooves are located so as to expose the filling material; disposing the wafer to a carrier board through its non-active surface, wherein the carrier board has a plurality of second conductive circuits formed thereon corresponding in position to the filling material; cutting the light permeable body and the wafer corresponding to the concave grooves to a position where the second conductive circuits are located, thereby forming a plurality of first openings; forming metallic layers on the second conductive circuits in the first openings, the metallic layers electrically connecting the first and second conductive circuits of adjacent sensor chips; cutting the metallic layers in the first openings so as to form second openings smaller in width than the first openings, thereby breaking the first conductive circuit connections and the second conductive circuit connections of adjacent sensor chips, and meanwhile keeping the first and second conductive circuits of each sensor chip still electrically connected through the metallic layers; filling a dielectric material into the second openings for covering the metallic layers, the first and second conductive circuits; and removing the carrier board and singulating the wafer so as to obtain a plurality of sensor-type semiconductor devices.

The carrier board is made of a metallic material and the second conductive circuits are formed thereon by electroplating. The metallic layers are formed on the second conductive circuits by electroplating through the carrier board of metallic material and the second conductive circuits.

According to another embodiment of the present invention, the manufacturing method of a sensor-type semiconductor device comprises the steps of: providing a wafer comprising a plurality of sensor chips, wherein the wafer and each sensor chip have an active surface and a non-active surface opposed to the active surface, a sensor area and a plurality of solder pads are disposed on the active surface of each sensor chip, and a plurality of concave grooves is formed between the solder pads of adjacent sensor chips; filling a filling material in the concave grooves and forming first conductive circuits on the filling material for electrically connecting the solder pads of adjacent sensor chips; disposing a light permeable body on the wafer for covering the sensor areas and thinning the non-active surface of the wafer to a position where the concave grooves are located so as to expose the filling material; cutting the light permeable body and the wafer between the sensor chips so as to separate the sensor chips from each other, wherein the first conductive circuits and the filling material are exposed from sides of the sensor chips; disposing the sensor chips to a carrier board having a plurality of second conductive circuits formed thereon, wherein there exists spacing between the sensor chips, the second conductive circuits are located between the sensor chips and exposed from the spacing; forming metallic layers on the second conductive circuits in the spacing, the metallic layers electrically connecting the first and second conductive circuits of adjacent sensor chips; cutting the metallic layer in the spacing so as to form openings smaller in width than the spacing, thereby breaking the first conductive circuit connections and the second conductive circuit connections of adjacent sensor chips, and meanwhile keeping the first and second conductive circuits of each sensor chip still electrically connected through the metallic layers; filling a dielectric material in the openings for covering the metallic layers, the first and second conductive circuits; and removing the carrier board and singulating the wafer so as to obtain a plurality of sensor-type semiconductor devices.

The present invention further discloses a sensor-type semiconductor device, which comprises: a sensor chip having an active surface and a non-active surface opposed to the active surface, a sensor area and a plurality of solder pads being disposed on the active surface of the sensor chip; first conductive circuits formed at periphery of the active surface of the sensor chip and electrically connected with the solder pads; second conductive circuits formed at periphery of the non-active surface of the senor chip; metallic layers formed on sides of the sensor chip for electrically connecting the first and second conductive circuits; and a light permeable body disposed on the active surface of the sensor chip and covering the sensor area.

The sensor-type semiconductor device further comprises a filling material disposed between the metallic layers and sides of the sensor chip; a dielectric material covering sides of the sensor chip and the light permeable body for covering the metallic layers and the first and second conductive circuits; and a solder mask layer covering the non-active surface of the sensor chip, which has openings for exposing part of the second conductive circuits such that conductive elements can be disposed to the exposed second conductive circuits for external electrical connection.

Therefore, according to the sensor-type semiconductor device and manufacturing method of the present invention, a wafer comprising a plurality of sensor chips is provided and a plurality of concave grooves is formed between solder pads on the active surface of adjacent sensor chips; a filling material is filled into the concave grooves and first conductive circuits are formed electrically connecting the solder pads of adjacent sensor chips; a light permeable body is disposed on the wafer and the non-active surface of the wafer is thinned to expose the filling material; the wafer is then disposed on a carrier board having a plurality of second conductive circuits formed corresponding in position to the filling material and the first conductive circuits; the light permeable body and the wafer are cut corresponding to the concave grooves to a position where the second conductive circuits are located, thereby forming first openings; metallic layers are formed in the first openings by electroplating and the metallic layers electrically connect the first and second conductive circuits of adjacent sensor chips; the metallic layers in the first openings are cut so as to form second openings smaller in width that the first openings, thus, the first conductive circuit connections and the second conductive circuit connections of adjacent sensor chips are broken, and meanwhile the first and second conductive circuits of each sensor chip can still be electrically connected through the metallic layers; a dielectric material is filled into the second openings so as to cover the metallic layers and the first and second conductive circuits; the carrier board is removed, and each of the sensor chips is separated from each other to form a plurality of sensor type semiconductor devices. Alternatively, the wafer can be thinned and singulated first, and then the obtained plurality of sensor chips is disposed on a carrier board with a plurality of second conductive circuits. Thereafter, such processes as forming metallic layers for electrically connecting the first and second conductive circuits, filling dielectrical material in the openings and breaking electrical connections between adjacent sensor chips are performed so as to obtain a plurality of sensor-type semiconductor devices. The invention prevents forming of slanting notches as in the prior art, prevents sharp angles from being formed at joints of electrical contacts and conductive circuits and further prevents displacement of the notches due to the difficulty in precise alignment, thus ensuring electrical connections between conductive circuits and protecting sensor chips from being damaged by concentrated stress. Further, as the dielectric material formed on sides of the sensor chip can protect the conductive circuits and the metallic layers from being polluted, the product reliability is ensured. Meanwhile, too much sputtering process and the plasma etching process are avoided to use in the present invention, thereby reducing the manufacturing cost and simplifying the manufacturing process.

### BRIEF DESCRIPTION OF DRAWINGS

FIGS. 1A and 1H are diagrams showing a WLCSP sensor-type semiconductor device and manufacturing method thereof according to U.S. Pat. No. 6,777,767;

FIGS. 2A to 2H are diagrams showing a sensor-type semiconductor device and manufacturing method thereof according to a first embodiment of the present invention;

FIG. 2I is a diagram showing a sensor-type semiconductor device with conductive elements disposed on bottom surface thereof; and

FIGS. 3A to 3F are diagrams showing a sensor-type semiconductor device and a manufacturing method thereof according to a second embodiment of the present invention.

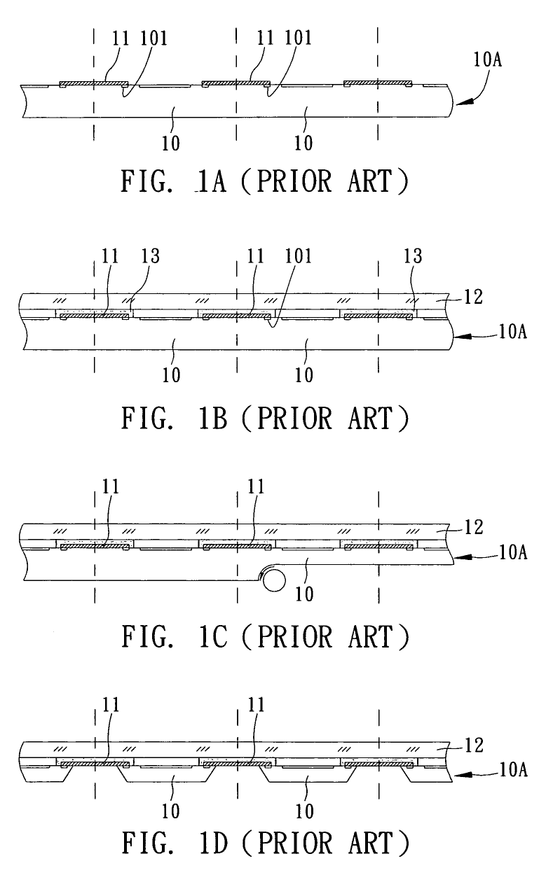

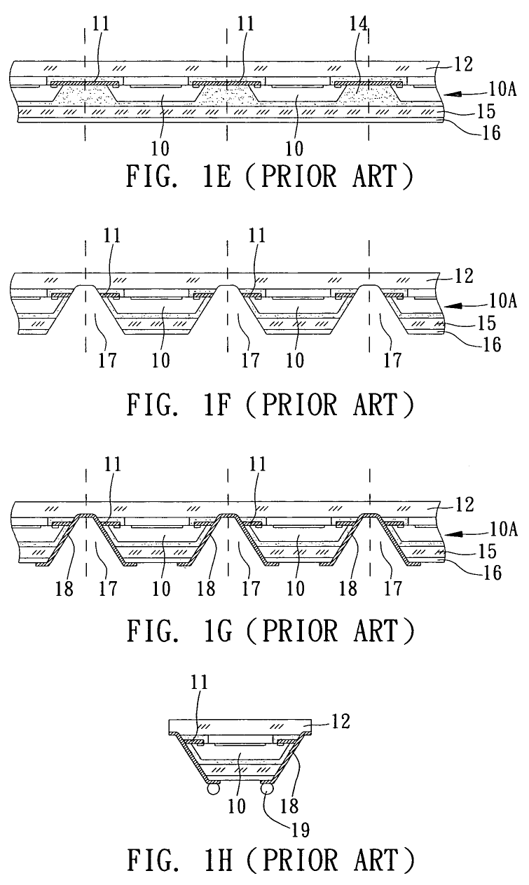

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

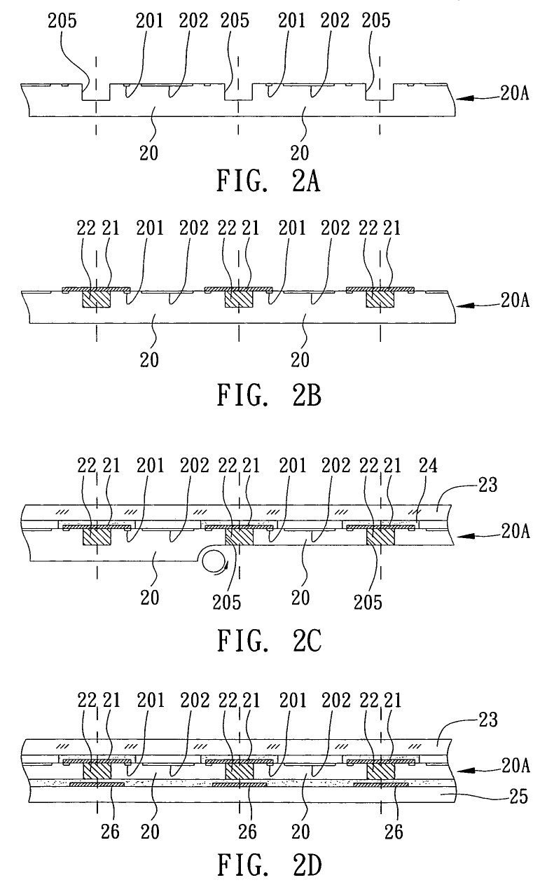

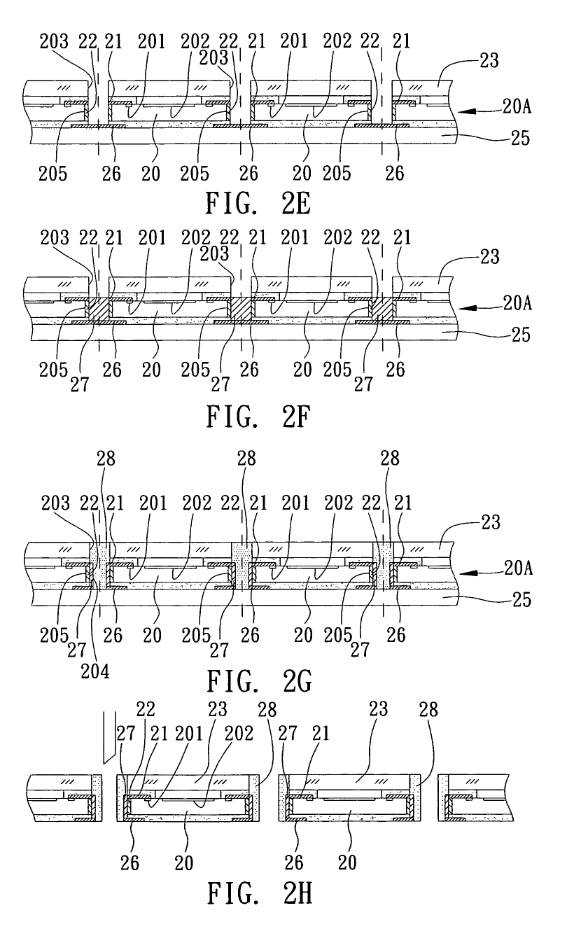

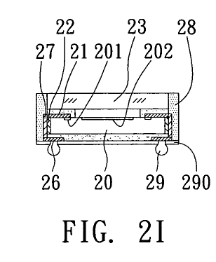

FIGS. 2A to 2H are diagrams showing a sensor-type semiconductor device and a manufacturing method thereof according to a first embodiment of the present invention.

As shown in FIG. 2A, a wafer 20A comprising a plurality of sensor chips 20 is provided. The wafer 20A and each sensor chip 20 have an active surface and a non-active surface opposed to the active surface. A sensor area 202 and a plurality of solder pads 201 are disposed on the active surface of each sensor chip 20. A plurality of concave grooves 205 is formed between the solder pads 201 of adjacent sensor chips 20. Each concave groove 205 has a width of approximately 100 μm and a depth of approximately 150 μm.

As shown in FIG. 2B, the concave grooves 205 are filled with a filling material 22 such as BCB (Benzo-Cyclo-Butene) or polyimide. The filling material 22 is then cured, and first conductive circuits 21 are further formed on the cured filling material 22 for electrically connecting the solder pads 201 of adjacent sensor chips 20. The first conductive circuits 21 can be TiW/Cu/electroplated Cu, Al/NiV/Cu/electroplated Cu or the like, which is about 1 μm to 5 μm thick and preferably 3 μm thick.

As shown in FIG. 2C, a light permeable body 23 is disposed on the wafer 20A, sealing and covering the sensor areas 202 of the sensor chips 20. The light permeable body 23 can be, for example, a glass, which is disposed on the wafer 20A through an adhesive layer 24 and covers the first conductive circuits 21 so as to seal and cover the sensor areas 202 of the sensor chips 20.

The non-active surfaces of the sensor chips 20 are then thinned to a position where the concave grooves 205 are located so as to expose the filling material 22 in the concave grooves 205.

As shown in FIG. 2D, the non-active surface of the wafer 20A is adhered to a carrier board 25 through an adhesive layer, wherein the carrier board 25 has a plurality of second conductive circuits 26 formed corresponding in position to the filling material 22 and the first conductive circuits 21.

The carrier board 25 can be a metallic board such as a copper board, on surface of which the second conductive circuits 26 are formed by electroplating. The second conductive circuits 26 can be Au/Ni, which is approximately 1 μm to 5 μm thick.

As shown in FIG. 2E, the light permeable body 23 and the wafer 20A are cut at positions corresponding to the concave grooves 205 to a position where the second conductive circuits 26 are located, thereby forming a plurality of first openings 203. The openings 203 are approximately 10 μm to 20 μm smaller than width of the concave grooves 205, and approximately 80 μm. The second conductive circuits 26 are exposed from the first openings 203 and part of the filling material 22 is left on sides of the sensor chips 20.

As shown in FIG. 2F, metallic layers 27 are formed on the second conductive circuits 26 by electroplating through the metallic carrier board 25 and the second conductive circuits 26. Therein, the metallic layers 27 electrically connect the first conductive circuits 21 and the second conductive circuits 26 of adjacent sensor chips 20. The metallic layers 27 may be made of such as Cu and Ni.

As shown in FIG. 2G, the metallic layers 27 in the first openings 203 are cut to a position where the carrier board 25 is located so as to form second openings 204, thereby breaking the first conductive circuit connections and the second conductive circuit connections of adjacent sensor chips 20. Meanwhile, as width of the second openings 204 is approximately 10 μm to 20 μm smaller than width of the first openings 203, and approximately 60 μm, part of the metallic layers 27 is left on the sides of the sensor chips 20 such that the first and second conductive circuits 21, 26 of each sensor chip 20 are still electrically connected through the metallic layers 27. Subsequently, a dielectric material 28 is filled in the second openings 204 so as to cover the metallic layers 27, the first and second conductive circuits 21, 26.

As shown in FIG. 2H, the carrier board 25 is removed by etching and the sensor chips 20 are separated from each other by cutting, thereby obtaining a plurality of sensor-type semiconductor devices.

Further referring to FIG. 2I, a solder mask layer 290 is formed on bottom of the sensor-type semiconductor device, and a plurality of openings are formed in the solder mask layer 290 for exposing part of the second conductive circuits 26. Conductive elements 29 such as bumps are disposed to the exposed second conductive circuits 26 such that the sensor-type semiconductor device can be electrically connected to an external device through the conductive elements 29.

Through the above described manufacturing method, a sensor-type semiconductor device is disclosed, which comprises: a sensor chip 20 having an active surface and a non-active surface opposed to the active surface, a sensor area 202 and a plurality of solder pads 201 being disposed on the active surface of the sensor chip 20; first conductive circuits 21 formed at periphery of the active surface of the sensor chip 20 and electrically connected with the solder pads 201; second conductive circuits 26 formed at periphery of the non-active surface of the sensor chip 20; metallic layers 27 formed on sides of the sensor chip 20 for electrically connecting the first and second conductive circuits 21, 26; and a light permeable body 23 disposed on the active surface of the sensor chip 20 and covering the sensor area 202 of the sensor chip 20.

The sensor-type semiconductor device further comprises a filling material 22 between the metallic layers 27 and sides of the sensor chip 20; a dielectric material 28 covering sides of the sensor chip 20 and the light permeable body 23 for covering the metallic layers 27 and the first and second conductive circuits 21, 26; and a solder mask layer 290 covering the non-active surface of the sensor chip 20, which has openings for exposing part of the second conductive circuits 26 such that conductive elements 29 can be disposed to the exposed second conductive circuits 26 for external electrical connection.

### Second Embodiment

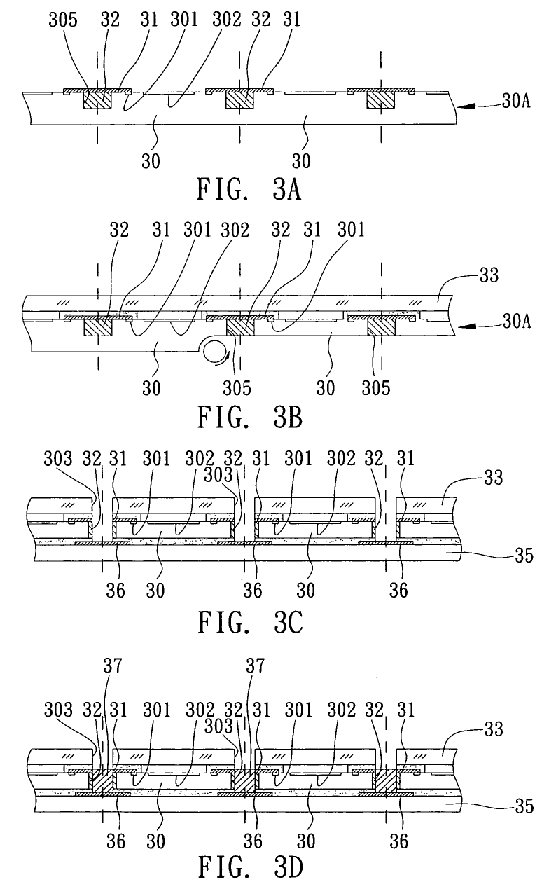

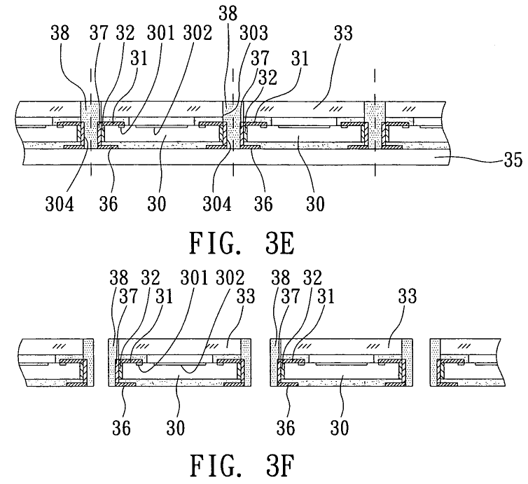

FIGS. 3A to 3F show a manufacturing method of a sensor-type semiconductor device according to a second embodiment of the present invention.

As shown in FIG. 3A, a wafer 30A having a plurality of sensor chips 30 is provided. The wafer 30A and each sensor chip 30 have an active surface and a non-active surface opposed to the active surface, and a sensor area 302 and a plurality of solder pads 301 are disposed on the active surface of each sensor chip 30. A plurality of concave grooves 305 is formed between the solder pads 301 of adjacent sensor chips 30. The concave grooves 305 are filled with a filling material 32, and first conductive circuits 31 are further formed on the filling material 32 for electrically connecting the solder pads 301 of adjacent sensor chips 30.

As shown in FIG. 3B, a light permeable body 33 is disposed on the wafer 30A, sealing and covering the sensor areas 302 of the sensor chips 30. The non-active surfaces of the sensor chips 30 are then thinned so as to expose the filling material 32 in the concave grooves 305.

As shown in FIG. 3C, the sensor chips 30 are separated from each other by cutting, wherein the first conductive circuits 31 and the filling material 32 are left on sides of the sensor chips 30. The sensor-types chips 30 arranged with spacing 303 from each other are adhered to a carrier board 35 through an adhesive layer and the carrier board 35 has a plurality of second conductive circuits 36 formed corresponding in position to the spacing 303 between the sensor chips 30 and exposed from the spacing 303.

As shown in FIG. 3D, metallic layers 37 are formed on the second conductive circuits 36 by electroplating, and the metallic layers 37 electrically connect the first conductive circuits 21 and the second conductive circuits 26 of adjacent sensor chips 30.

As shown in FIG. 3E, the metallic layers 37 are cut so as to form openings 304, thereby breaking the first conductive circuit connections and the second conductive circuit connections of adjacent sensor chips 30. As width of the openings 304 is smaller than width of the spacing 303, part of the metallic layers 37 is left on sides of the sensor chips 30 such that the first and conductive circuits 31, 36 of each sensor chip 30 can still be electrically connected through the metallic layers 37. Subsequently, a dielectric material 38 is filled in the openings 304 so as to seal the metallic layers 37, the first and second conductive circuits 31, 36.

As shown in FIG. 3F, the carrier board 35 is removed by etching and the sensor chips 30 are separated from each other by cutting, thereby obtaining a plurality of sensor-type semiconductor devices.

A solder mask layer is formed on bottom of the sensor-type semiconductor device, and a plurality of openings are formed in the solder mask layer for exposing part of the second conductive circuits 36. Conductive elements such as bumps are disposed to the exposed second conductive circuits 36 such that the sensor-type semiconductor device can be electrically connected to an external device through the conductive elements.

Therefore, according to the sensor-type semiconductor device and manufacturing method of the present invention, a wafer comprising a plurality of sensor chips is provided and a plurality of concave grooves is formed between the solder pads on the active surface of adjacent sensor chips; a filling material is filled into the concave grooves and first conductive circuits are formed electrically connecting the solder pads of adjacent sensor chips; a light permeable body is disposed on the wafer and the non-active surface of the wafer is thinned to expose the filling material; the wafer is then disposed on a carrier board having a plurality of second conductive circuits formed corresponding in position to the filling material and the first conductive circuits; the light permeable body and the wafer are cut corresponding to the concave grooves to a position where the second conductive circuits are located, thereby forming first openings; metallic layers are formed in the first openings and electrically connect the first and second conductive circuits of adjacent sensor chips; the metallic layers in the first openings are cut so as to form second openings smaller in width than the first openings, thus, the first conductive circuit connections and the second conductive circuit connections of adjacent sensor chips are broken, and meanwhile the first and second conductive circuits of each sensor chip can still be electrically connected through the metallic layers; a dielectric material is filled into the second openings so as to cover the metallic layer and the first and second conductive circuits; the carrier board is removed, and each of the sensor chips is separated from each other to form a plurality of sensor type semiconductor devices. Alternatively, the wafer can be thinned and singulated first, and then the obtained plurality of sensor chips is disposed on a carrier board with a plurality of second conductive circuits. Thereafter, such processes as forming metallic layers for electrically connecting the first and second conductive circuits, filling dielectrical material in openings and breaking electrical connections between adjacent sensor chips are performed so as to obtain a plurality of sensor-type semiconductor devices. The invention prevents forming of slanting notches as in the prior art, prevents sharp angles from being formed at joints of electrical contacts and conductive circuits and further prevents displacement of the notches due to the difficulty in precise alignment concentrated stress, thus ensuring electrical connections between conductive circuits and protecting sensor chips from being damaged by concentrated stress. Further, as the dielectric material formed on sides of the sensor chip can protect the conductive circuits and the metallic layers from being polluted, the product reliability is ensured. Meanwhile, too much sputtering process and the plasma etching process are avoided to use in the present invention, thereby reducing the manufacturing cost and simplifying the manufacturing process.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A manufacturing method of a sensor-type semiconductor device, comprising the steps of:
providing a wafer comprising a plurality of sensor chips, wherein the wafer and each sensor chip have an active surface and a non-active surface opposed to the active surface, a sensor area and a plurality of solder pads are disposed on the active surface of each sensor chip, and a plurality of concave grooves is formed between the solder pads of adjacent sensor chips;
filling a filling material into the concave grooves and forming first conductive circuits on the filling material for electrically connecting the solder pads of adjacent sensor chips;
disposing a light permeable body on the wafer for covering the sensor areas and thinning the non-active surface of the wafer to a position where the concave grooves are located so as to expose the filling material;
disposing the wafer to a carrier board through its non-active surface, wherein the carrier board has a plurality of second conductive circuits formed thereon corresponding in position to the filling material;
cutting the light permeable body and the wafer corresponding to the concave grooves to a position where the second conductive circuits are located, thereby forming a plurality of first openings;
forming metallic layers on the second conductive circuits in the first openings, the metallic layers electrically connecting the first and second conductive circuits of adjacent sensor chips;
cutting the metallic layers in the first openings so as to form second openings smaller in width than the first openings, thereby breaking the first conductive circuit connections and the second conductive circuit connections of adjacent sensor chips, and meanwhile keeping the first and second conductive circuits of each sensor chip still electrically connected through the metallic layers;
filling a dielectric material into the second openings for covering the metallic layers, the first and second conductive circuits; and
removing the carrier board and singulating the wafer so as to obtain a plurality of sensor-type semiconductor devices.

2. The manufacturing method of claim 1, wherein the concave grooves are approximately 100 μm wide and 150 μm deep, the width of the first openings are approximately 10 to 20 μm smaller than that of the concave grooves and approximately 80 μm, thus the second conductive circuits are exposed from the first openings and meanwhile part of the filling material is left on sides of the sensor chips.

3. The manufacturing method of claim 1, wherein the light permeable body is a glass, which is disposed to the active surface of the wafer through an adhesive layer for sealing and covering the sensor areas of the sensor chips.

4. The manufacturing method of claim 1, wherein the non-active surface of the wafer is adhered to the carrier board through an adhesive layer, the carrier board is made of a metallic material, the second conductive circuits are formed on the carrier board by electroplating.

5. The manufacturing method of claim 1, wherein the metallic layers are formed on the second conductive circuits in the first openings by electroplating through the carrier board of metallic material and the second conductive circuits.

6. The manufacturing method of claim 1, wherein width of the second openings is approximately 10 μm to 20 μm smaller than that of the first openings and approximately 60 μm, as a result, part of the metallic layers is left on sides of the sensor chips for electrically connecting the first and second conductive circuits of each sensor chip.

7. The manufacturing method of claim 1 further comprising a step of covering the bottom of the semiconductor device with a solder mask layer and forming a plurality of openings in the solder mask layer such that part of the second conductive circuits can be exposed from the openings and conductive elements can be disposed on the exposed second conductive circuits.

8. A manufacturing method of a sensor-type semiconductor device, comprising the steps of:
providing a wafer comprising a plurality of sensor chips, wherein the wafer and each sensor chip have an active surface and a non-active surface opposed to the active surface, a sensor area and a plurality of solder pads are disposed on the active surface of each sensor chip, and a plurality of concave grooves is formed between the solder pads of adjacent sensor chips;
filling a filling material in the concave grooves and forming first conductive circuits on the filling material for electrically connecting the solder pads of adjacent sensor chips;
disposing a light permeable body on the wafer for covering the sensor areas and thinning the non-active surface of the wafer to a position where the concave grooves are located so as to expose the filling material;
cutting the light permeable body and the wafer between the sensor chips so as to separate the sensor chips from each other, wherein the first conductive circuits and the filling material are exposed from sides of the sensor chips;
disposing the sensor chips to a carrier board having a plurality of second conductive circuits formed thereon, wherein there exists spacing between the sensor chips, the second conductive circuits are located between the sensor chips and exposed from the spacing;
forming metallic layers on the second conductive circuits in the spacing, the metallic layers electrically connecting the first and second conductive circuits of adjacent sensor chips;
cutting the metallic layer in the spacing so as to form-openings smaller in width than the spacing, thereby breaking the first conductive circuit connections and the second conductive circuit connections of adjacent sensor chips, and meanwhile keeping the first and second conductive circuits of each sensor chip still electrically connected through the metallic layers;
filling a dielectric material in the openings for covering the metallic layers, the first and second conductive circuits; and
removing the carrier board and singulating the wafer so as to obtain a plurality of sensor-type semiconductor devices.

9. The manufacturing method of claim 8, wherein the light permeable body is a glass, which is disposed to the active surface of the wafer through an adhesive layer for sealing and covering the sensor areas of the sensor chips.

10. The manufacturing method of claim 8, wherein the sensor chips are adhered to the carrier board through non-active surface thereof, imposed with an adhesive layer, the carrier board is made of a metallic material, the second conductive circuits are formed on the carrier board by electroplating.

11. The manufacturing method of claim 8, wherein the metallic layers are formed on the second conductive circuits in the spacing by electroplating through the carrier board of metallic material and the second conductive circuits.

12. The manufacturing method of claim 8 further comprising a step of covering the bottom of the semiconductor device with a solder mask layer and forming a plurality of openings in the solder mask layer such that part of the second conductive circuits can be exposed from the openings and conductive elements can be disposed on the exposed second conductive circuits.

13. A sensor-type semiconductor device, comprising:
a sensor chip having an active surface and a non-active surface opposed to the active surface, a sensor area and a plurality of solder pads disposed on the active surface of the sensor chip;
first conductive circuits formed at periphery of the active surface of the sensor chip and electrically connected with the solder pads;
second conductive circuits formed at periphery of the non-active surface of the senor chip;
metallic layers formed on sides of the sensor chip for electrically connecting the first and second conductive circuits; and
a light permeable body disposed on the active surface of the sensor chip and covering the sensor area.

14. The device of claim 13 further comprising a filling material disposed between the metallic layers and sides of the sensor chip.

15. The device of claim 13 further comprising a dielectric material, which covers sides of the sensor chip and the light permeable body so as to cover the metallic layers, the first and second conductive circuits.

16. The device of claim 13 further comprising a solder mask layer covering the non-active surface of the sensor chip, which has openings formed for exposing part of the second conductive circuits such that conductive elements can be disposed on the exposed second conductive circuits.

17. The device of claim 13, wherein the light permeable body is a glass, which is disposed on the active surface of the senor chip through an adhesive layer so as to seal and cover the sensor area.
